(19) United States
(12) Patent Application Publication
(10) Pub. No.: US 2010/0190272 A1
(43) Pub. Date: Jul. 29, 2010

(54) REWORK METHOD OF METAL HARD MASK

(75) Inventors: Yu Zhang, Singapore (SG); Bin Zhao, Singapore (SG); Kah-Lun Toh, Singapore (SG); Shi-Jie Bai, Singapore (SG)

Correspondence Address: NORTH AMERICA INTELLECTUAL PROPERTY CORPORATION, P.O. BOX 506, MERRIFIELD, VA, 22116, US

(73) Assignee: UNITED MICROELECTRONICS CORP., Hsinchu (TW)

(21) Appl. No.: 12/358,914

(22) Filed: Jan. 23, 2009

(51) Int. Cl. H01L 21/302; H01L 21/44; H01L 21/02

(52) U.S. Cl. 438/4; 438/692; 438/685; 257/E21.002; 257/E21.23; 257/E21.295

(57) ABSTRACT

A rework method of a metal hard mask layer is provided. First, a material layer is provided. A dielectric layer, a first metal hard mask layer, and a patterned first dielectric hard mask layer have been sequentially formed on the material layer. There is a defect on a region of the first metal hard mask layer, and therefore the region of the first metal hard mask layer is not able to be patterned. After that, the patterned first dielectric hard mask layer and the first metal hard mask layer are removed. A planarization process is then performed on the dielectric layer. Next, a second metal hard mask layer and a second dielectric hard mask layer are sequentially formed on the dielectric layer.

### BACKGROUND OF THE INVENTION

1. Field of the Invention

The present invention relates to a semiconductor manufacturing process. More particularly, the present invention relates to a rework method of a metal hard mask layer.

2. Description of Related Art

A manufacturing process of a wafer is complicated. Fabrication of the wafer is usually subject to repetitive deposition, etching, and photolithography steps. Hence, once foreign materials including particles fall onto the wafer during the fabrication thereof, the subsequent deposition, etching, and photolithography steps may not be well implemented, and therefore a rework process is required to be performed on the wafer.

For instance, in a general damascene process, a metal hard mask layer and a patterned dielectric hard mask layer are sequentially formed on a dielectric layer at first. Next, the metal hard mask layer is patterned with use of the patterned dielectric hard mask layer as a mask. However, due to particles deposited on a portion of the metal hard mask layer or other reasons, patterns of the dielectric hard mask layer are not able to be transferred to the portion of the metal hard mask layer where the particles are deposited. As a result, the dimension of openings formed in the dielectric layer with use of the metal hard mask layer as the mask is not compliant with the critical dimension (CD), and thereby issues including metal bridge may occur. Therefore, when defects caused by particles deposited on the metal hard mask layer are inspected, it is necessary to perform a rework process on the metal hard mask layer; otherwise, subsequent steps may be adversely affected, and the wafer formed thereby may have to be scrapped.

In view of the above, the metal hard mask layer is frequently utilized in the semiconductor manufacturing process. As such, it is imperious to develop a rework method of a metal hard mask layer for reducing a rejection rate of the wafer and improving yield of the same.

### SUMMARY OF THE INVENTION

The present invention is directed to a rework method of a metal hard mask layer for reducing a rejection rate of a wafer and improving yield of the same.

A rework method of a metal hard mask layer is provided in the present invention. In the rework method, a material layer is first provided. A dielectric layer, a first metal hard mask layer, and a patterned first dielectric hard mask layer are already formed sequentially on the material layer. Since there is a defect on a region of the first metal hard mask layer, the region of the first metal hard mask layer is not able to be patterned. After that, the patterned first dielectric hard mask layer and the first metal hard mask layer are removed. A planarization process is then performed on the dielectric layer. Next, a second metal hard mask layer and a second dielectric hard mask layer are sequentially formed on the dielectric layer.

In an embodiment of the present invention, a method of removing the patterned first dielectric hard mask layer and the first metal hard mask layer includes performing an etchback process.

In an embodiment of the present invention, a method of removing the patterned first dielectric hard mask layer and the first metal hard mask layer includes performing a chemical-mechanical polishing (CMP) process.

In an embodiment of the present invention, the rework method of the metal hard mask layer further includes removing the defect before the patterned first dielectric hard mask layer and the first metal hard mask layer are removed.

In an embodiment of the present invention, the rework method of the metal hard mask layer further includes forming a dielectric material layer on the material layer after the planarization process is performed on the dielectric layer.

In an embodiment of the present invention, the rework method of the metal hard mask layer further includes performing a planarization process on the dielectric material layer after the dielectric material layer is formed on the material layer.

In an embodiment of the present invention, the planarization process is a CMP process.

In an embodiment of the present invention, a material of the first metal hard mask layer includes titanium nitride.

In an embodiment of the present invention, a material of the first dielectric hard mask layer includes plasma enhanced oxide (PEOX).

The present invention further provides a rework method of a metal hard mask layer. In the rework method, a material layer is provided. A dielectric layer, a metal hard mask layer, and a patterned dielectric hard mask layer are already formed sequentially on the material layer. Since there is a defect on a region of the metal hard mask layer, the region of the metal hard mask layer is not able to be patterned. The defect is then removed. Thereafter, the region of the metal hard mask layer is removed with use of an etchant until the dielectric layer is exposed. The etchant has a high etching selectivity ratio with respect to the metal hard mask layer and the dielectric hard mask layer.

In an embodiment of the present invention, a material of the metal hard mask layer includes titanium nitride.

In an embodiment of the present invention, a material of the dielectric hard mask layer includes PEOX.

In an embodiment of the present invention, a material of the dielectric layer includes tetra-ethyl-ortho-silicate (TEOS).

In an embodiment of the present invention, the etchant includes Cl₂/HBr/CF₄.

The present invention further provides a rework method of a metal hard mask layer. First, a material layer is provided. A first dielectric layer, a second dielectric layer, a third dielectric layer, and a patterned first metal hard mask layer are sequentially formed on the material layer. Here, the second dielectric layer, the third dielectric layer, and the patterned first metal hard mask layer have an opening, and the opening does not expose the first dielectric layer. Next, a fourth dielectric layer is formed on the material layer. The fourth dielectric layer fills the opening. Thereafter, the patterned first metal hard mask layer, the fourth dielectric layer, the third dielectric layer, and the second dielectric layer are removed. After that, a fifth dielectric layer, a sixth dielectric layer, a second metal hard mask layer, and a dielectric hard mask layer are sequentially formed on the first dielectric layer.

In an embodiment of the present invention, a method of forming the fourth dielectric layer includes following steps. First, a dielectric material layer is formed on the material layer. The dielectric material layer fills the opening and covers the patterned first metal hard mask layer. Next, a portion of the dielectric material layer is removed, and a top surface of the patterned first metal hard mask layer is an end point of the removal step.

In an embodiment of the present invention, a method of removing the patterned first metal hard mask layer includes utilizing a metal etching machine.

In an embodiment of the present invention, a method of removing the third dielectric layer includes first removing a portion of the third dielectric layer by performing a planarization process and then removing the remaining third dielectric layer.

In an embodiment of the present invention, a method of removing the remaining third dielectric layer includes utilizing an etchant which has a high etching selectivity ratio with respect to the third dielectric layer and the second dielectric layer.

In an embodiment of the present invention, a method of removing the second dielectric layer includes utilizing an etchant which has a high etching selectivity ratio with respect to the second dielectric layer and the first dielectric layer.

Based on the above, the rework method of the metal hard mask layer in the present invention can be applied to remove the dielectric layer, the metal hard mask layer, and the dielectric hard mask layer without affecting characteristics of the wafer. Thereby, another dielectric layer, another metal hard mask layer, and another dielectric hard mask layer can be formed on the wafer, and loss caused by discarding the scrapped wafer can be avoided. Hence, by applying the rework method of the metal hard mask layer in the present invention, the rejection rate of the wafer can be significantly reduced, and the yield of the wafer can be improved. As such, manufacturing costs of the wafer can be lowered down.

In order to make the aforementioned and other features and advantages of the present invention more comprehensible, several embodiments accompanied with figures are described in detail below.

### BRIEF DESCRIPTION OF THE DRAWINGS

The accompanying drawings constituting a part of this specification are incorporated herein to provide a further understanding of the invention. Here, the drawings illustrate embodiments of the invention and, together with the description, serve to explain the principles of the invention.

FIGS. 1A to 1D are schematic cross-sectional views illustrating processes of a rework method of a metal hard mask layer according to a first embodiment of the present invention.

FIGS. 2A to 2B are schematic cross-sectional views illustrating processes of a rework method of a metal hard mask layer according to a second embodiment of the present invention.

FIGS. 3A to 3F are schematic cross-sectional views illustrating processes of a rework method of a metal hard mask layer according to a third embodiment of the present invention.

### DESCRIPTION OF EMBODIMENTS

In general, after the dielectric hard mask layer and the metal hard mask layer are patterned and a contact opening is completely formed, said manufacturing steps are inspected, so as to determine if a rework process is necessary. Given that the metal hard mask layer is found not to be properly patterned after the dielectric hard mask layer and the metal hard mask layer are patterned, a rework method of a metal hard mask layer as discussed in a first embodiment and a second embodiment can be applied. On the other hand, when some contact openings are not well formed after the fabrication of the contact openings is completed, a rework method of a metal hard mark layer as provided in a third embodiment can be conducted.

### First Embodiment

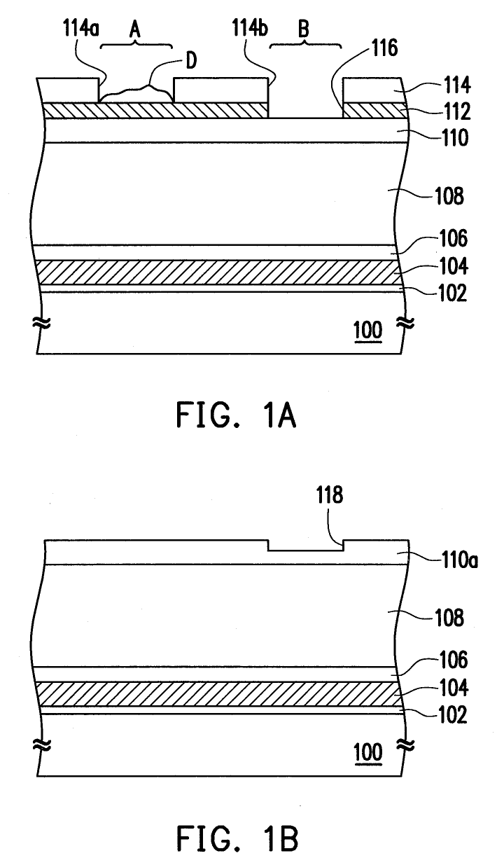

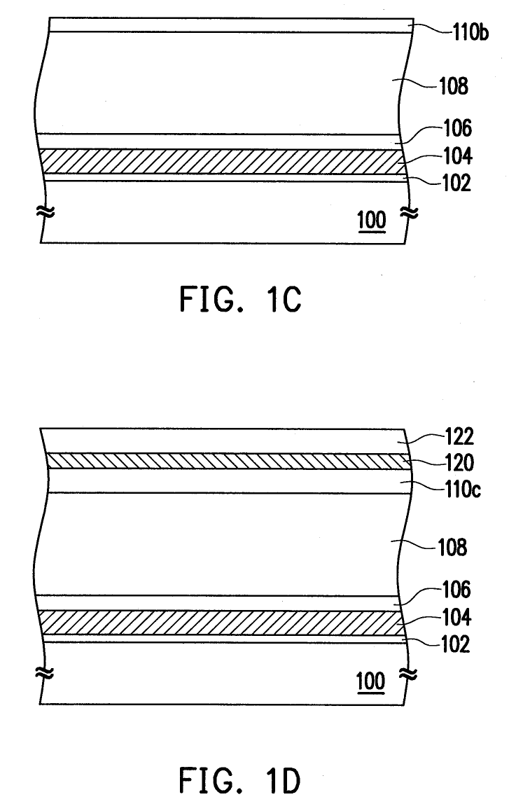

FIGS. 1A to 1D are schematic cross-sectional views illustrating processes of a rework method of a metal hard mask layer according to a first embodiment of the present invention.

Referring to FIG. 1A, a substrate 100 is provided. An insulating layer 102, a conductive layer 104, a first dielectric layer 106, a second dielectric layer 108, a third dielectric layer 110, a metal hard mask layer 112, and a patterned dielectric hard mask layer 114 are already formed sequentially on the substrate 100. The metal hard mask layer 112 is not entirely patterned. In detail, after the formation of the patterned dielectric hard mask layer 114, the defect D, e.g., particles or the like, deposited on the region A of the metal hard mask layer 112, for example. Thereby, when the opening patterns 114a and 114b of the patterned dielectric hard mask layer 114 are transferred to the metal hard mask layer 112, the opening patterns 114b is transferred to the region B of the metal hard mask layer 112 as an opening pattern 116 and the opening patterns 114a is not able to transferred to the region A of the metal hard mask layer 112. In the present embodiment, the substrate 100 is, for example, a silicon substrate. A material of the insulating layer 102 is, for example, silicon oxide or any other suitable dielectric material. A material of the conductive layer 104 is, for example, copper, a copper alloy, or any other conductive material. A material of the first dielectric layer 106 is, for example, silicon nitride, silicon carbon, or any other appropriate dielectric material. A material of the second dielectric layer 108 is, for example, a material having a low dielectric constant. A material of the third dielectric layer 110 is tetra-ethyl-ortho-silicate (TEOS), for example. A material of the metal hard mask layer 112 is, for example, titanium nitride, tantalum nitride, or a titanium-tungsten alloy. A material of the dielectric hard mask layer 114 is, for example, plasma enhanced oxide (PEOX) such as plasma enhanced silicon oxide.

Referring to FIG. 1B, the patterned dielectric hard mask layer 114 and the metal hard mask layer 112 are then removed. In the present embodiment, a method of removing the patterned dielectric hard mask layer 114 and the metal hard mask layer 112 includes performing an etchback process or a chemical-mechanical polishing (CMP) process. Note that the defect D can be removed by solvent cleaning, etchback process or CMP process before the patterned dielectric hard mask layer 114 and the metal hard mask layer 112 are removed. Moreover, in the step of removing the patterned dielectric hard mask layer 114 and the metal hard mask layer 112, a portion of the third dielectric layer 110 may be removed as well, so as to form a third dielectric layer 110a having a recess 118.

Referring to FIG. 1C, to prevent subsequent processes from being affected by the recess 118, a planarization process is performed on the third dielectric layer 110a, so as to form a third dielectric layer 110b. In the present embodiment, the planarization process is, for example, a CMP process.

As indicated in FIG. 1D, a dielectric material layer (not shown) is then formed on the substrate 100 by deposition, and a planarization process is performed on the dielectric material layer, so as to form a third dielectric layer 110c having a planar surface. A thickness of the third dielectric layer 110c is the same as a thickness of the third dielectric layer 110 depicted in FIG. 1A, for example. It should be mentioned that the step of depositing the dielectric material layer and planarizing the dielectric layer material can be repeated, such that the third dielectric layer 110c can have a desired thickness and the planar surface.

After that, a metal hard mask layer 120 and a dielectric hard mask layer 122 are sequentially formed on the substrate 100. A material of the metal hard mask layer 120 is, for example, titanium nitride, tantalum nitride, or a titanium-tungsten alloy, and a method of forming the metal hard mask layer 120 includes performing a chemical vapor deposition (CVD) process, for instance. Besides, a material of the dielectric hard mask layer 122 is, for example, PEOX, and a method of forming the dielectric hard mask layer 122 includes performing a plasma enhanced CVD process, for example.

### Second Embodiment

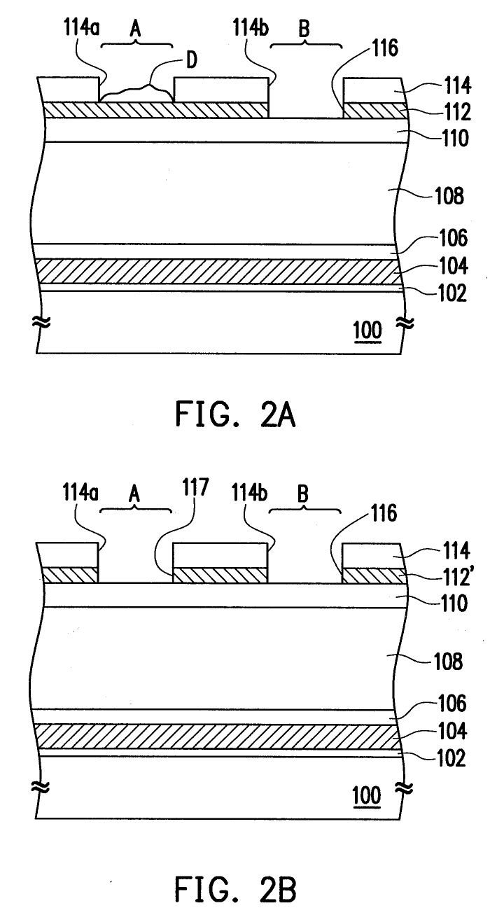

FIGS. 2A to 2B are schematic cross-sectional views illustrating processes of a rework method of a metal hard mask layer according to a second embodiment of the present invention.

Referring to FIG. 2A, a substrate 100 is provided. An insulating layer 102, a conductive layer 104, a first dielectric layer 106, a second dielectric layer 108, a third dielectric layer 110, a metal hard mask layer 112, and a patterned dielectric hard mask layer 114 are already formed sequentially on the substrate 100. The metal hard mask layer 112 is not entirely patterned. Here, materials and characteristics of the insulating layer 102, the conductive layer 104, the first dielectric layer 106, the second dielectric layer 108, the third dielectric layer 110, the metal hard mask layer 112, and the patterned dielectric hard mask layer 114 can be referred to as those described in the first embodiment, and so can a reason for inducing the defect D. Therefore, relevant descriptions are not further provided hereafter.

Referring to FIG. 2B, next, the defect D is removed. A method of removing the defect D is solvent cleaning, etchback process or CMP process, for example.

Thereafter, the region A of the metal hard mask layer 112 is removed by using an etchant until the third dielectric layer 110 is exposed, so as to form a patterned metal hard mask layer 112′. In other words, an opening pattern 114a of the dielectric hard mask layer 114 is transferred to the metal hard mask layer 112, such that the region A of the metal hard mask layer 112 has an opening pattern 117 which exposes the third dielectric layer 110. Thus, the opening patterns 114a and 114b of the dielectric hard mask layer 114 are all transferred to the metal hard mask layer 112 completely. Here, the etchant has a high etching selectivity ratio with respect to the metal hard mask layer 112 and the dielectric hard mask layer 114, and the etchant is, for example, Cl₂/HBr.

After that, damascene openings (not shown) and the like are, for example, formed in the dielectric layers 106, 108, and 110 with use of the dielectric hard mask layer 114 and the metal hard mask layer 112 as a mask. Subsequent semiconductor manufacturing processes performed by using the dielectric hard mask layer 114 and the metal hard mask layer 112 as the mask are well known to people having ordinary skill in the art, and therefore no further descriptions are provided herein.

### Third Embodiment

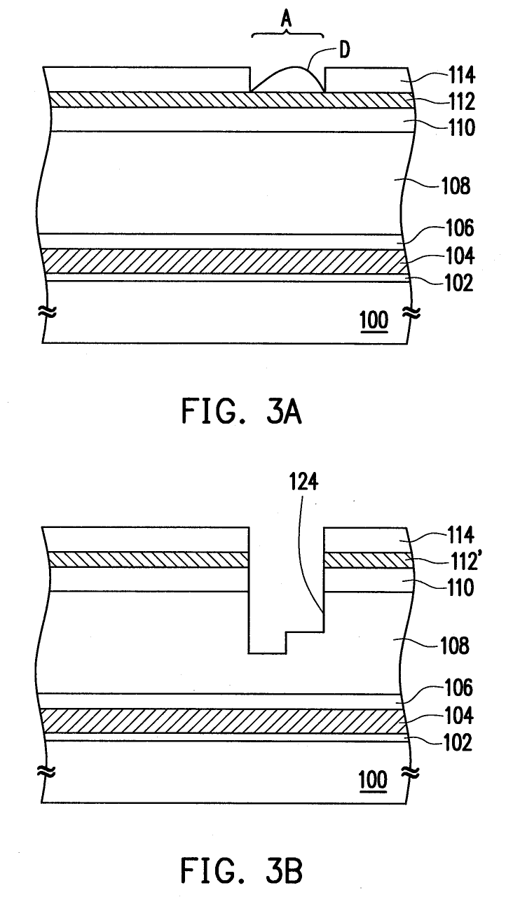

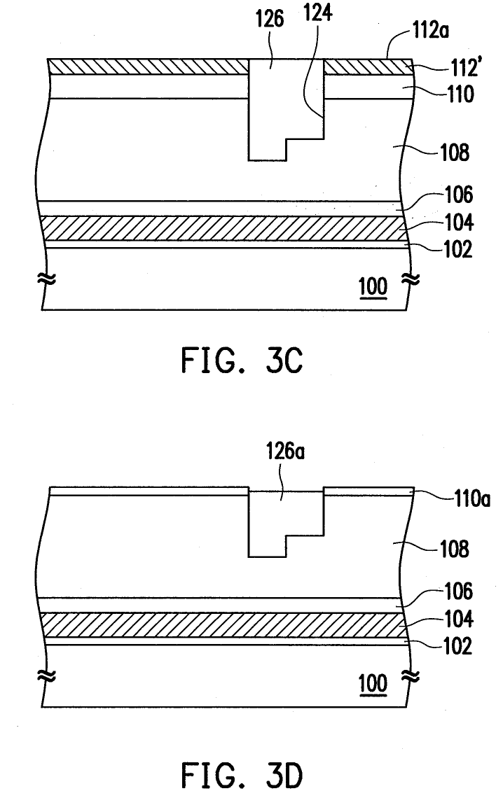

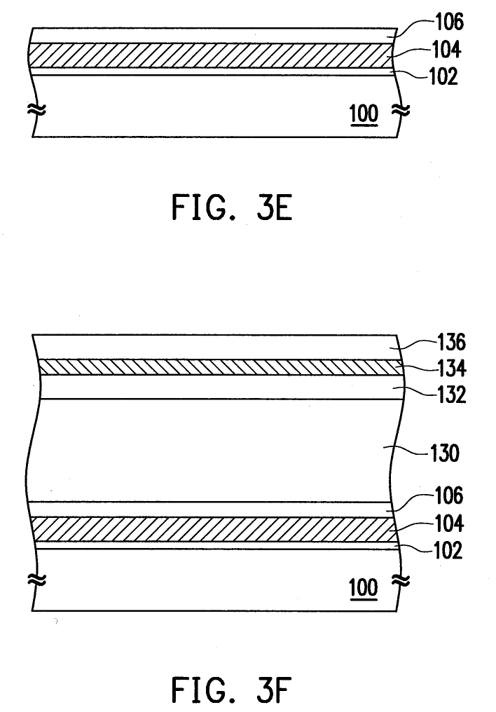

FIGS. 3A to 3F are schematic cross-sectional views illustrating processes of a rework method of a metal hard mask layer according to a third embodiment of the present invention.

Referring to FIG. 3A, a substrate 100 is provided. An insulating layer 102, a conductive layer 104, a first dielectric layer 106, a second dielectric layer 108, a third dielectric layer 110, a metal hard mask layer 112, and a patterned dielectric hard mask layer 114 are already formed sequentially on the substrate 100. The defect D existing on the region A of the metal hard mask layer 112 is, for example, referred to as particles falling onto the metal hard mask layer 112 after the formation of the patterned dielectric hard mask layer 114. Here, materials and characteristics of the insulating layer 102, the conductive layer 104, the first dielectric layer 106, the second dielectric layer 108, the third dielectric layer 110, the metal hard mask layer 112, and the patterned dielectric hard mask layer 114 can be referred to as those described in the first embodiment. Therefore, relevant descriptions are not further provided hereafter.

Referring to FIG. 3B, next, a portion of the metal hard mask layer 112, a portion of the third dielectric layer 110, and a portion of the second dielectric layer 108 are removed with use of the patterned dielectric hard mask layer 114 as a mask, so as to form a patterned metal hard mask layer 112′ and an opening 124 that does not expose the first dielectric layer 106. In the present embodiment, the defect D is located on the region A of the metal hard mask layer 112, and therefore the opening 124 is not deep enough to expose the first dielectric layer 106. Accordingly, the dimension of the opening 124 is not compliant with the critical dimension (CD), and a rework process is thus required.

Referring to FIG. 3C, the patterned dielectric hard mask layer 114 is then removed. Thereafter, a dielectric layer 126 is formed on the substrate 100. The opening 124 is filled with the dielectric layer 126. In detail, a dielectric material layer (not shown) is formed on the substrate 100. The dielectric material layer fills the opening 124 and covers the patterned metal hard mask layer 112′. After that, the dielectric material layer is partially removed by performing a CMP process, for example, and a top surface 112a of the patterned metal hard mask layer 112′ is an end point of the removal step, such that the dielectric layer 126 is formed. Here, the dielectric material layer and the second dielectric layer 108 are, for example, made of the same material having the low dielectric constant. Additionally, the dielectric material layer is formed by performing a CVD process, for example.

Referring to FIG. 3D, after that, the patterned metal hard mask layer 112′ is removed by a metal etching machine, for example. In this step, a portion of the dielectric layer 126 is likely to be removed as well, so as to form a dielectric layer 126a. Afterwards, a portion of the third dielectric layer 110 is removed by performing a CMP process, for example, so as to form a third dielectric layer 110a.

Referring to FIG. 3E, the remaining third dielectric layer 110a is, for example, removed with use of a first etchant which has a high etching selectivity ratio with respect to the third dielectric layer 110a and the second dielectric layer 108. The first etchant is, for example, Cl₂/HBr.

Next, the second dielectric layer 108 is, for example, removed with use of a second etchant which has a high etching selectivity ratio with respect to the second dielectric layer 108 and the first dielectric layer 106. The second etchant is, for example, CHF₃.

As shown in FIG. 3F, thereafter, a dielectric layer 130, a dielectric layer 132, a metal hard mask layer 134, and a dielectric hard mask layer 136 are sequentially formed on the first dielectric layer 106. In the present embodiment, a material of the dielectric layer 130 is, for example, a material having a low dielectric constant or any other appropriate dielectric material. A material of the dielectric layer 132 is TEOS, for example. A material of the metal hard mask layer 134 is, for example, titanium nitride, tantalum nitride, or a titanium-tungsten alloy. A material of the dielectric hard mask layer 136 is, for example, PEOX such as plasma enhanced silicon oxide or any other appropriate material.

To sum up, when the metal hard mask layer is found not to be properly patterned after the metal hard mask layer is patterned or the contact opening is completely formed, the rework method of the metal hard mask layer of the present invention can be applied. Based on the above, the dielectric layer, the metal hard mask layer, and the dielectric hard mask layer can be removed without affecting characteristics of a wafer, and another dielectric layer, another metal hard mask layer, and another dielectric hard mask layer can then be formed on the wafer. Thereby, loss caused by discarding a scrapped wafer can be avoided. Hence, by applying the rework method of the metal hard mask layer in the present invention, the rejection rate of the wafer can be significantly reduced, and the yield of the wafer can be improved. As such, manufacturing costs of the wafer can be lowered down.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A rework method of a metal hard mask layer, comprising:
providing a material layer on which a dielectric layer, a first metal hard mask layer, and a patterned first dielectric hard mask layer are sequentially formed, wherein there is a defect on a region of the first metal hard mask layer, and the region of the first metal hard mask layer is not able to be patterned;
removing the patterned first dielectric hard mask layer and the first metal hard mask layer;
performing a planarization process on the dielectric layer; and
sequentially forming a second metal hard mask layer and a second dielectric hard mask layer on the dielectric layer.

2. The rework method of the metal hard mask layer as claimed in claim 1, wherein a method of removing the patterned first dielectric hard mask layer and the first metal hard mask layer comprises performing an etchback process.

3. The rework method of the metal hard mask layer as claimed in claim 1, wherein a method of removing the patterned first dielectric hard mask layer and the first metal hard mask layer comprises performing a chemical-mechanical polishing process.

4. The rework method of the metal hard mask layer as claimed in claim 1, further comprising removing the defect before the patterned first dielectric hard mask layer and the first metal hard mask layer are removed.

5. The rework method of the metal hard mask layer as claimed in claim 1, further comprising forming a dielectric material layer on the material layer after the dielectric layer is planarized.

6. The rework method of the metal hard mask layer as claimed in claim 5, further comprising performing a planarization process on the dielectric material layer after the dielectric material layer is formed on the material layer.

7. The rework method of the metal hard mask layer as claimed in claim 1, wherein the planarization process is a chemical-mechanical polishing process.

8. The rework method of the metal hard mask layer as claimed in claim 1, wherein a material of the first metal hard mask layer comprises titanium nitride.

9. The rework method of the metal hard mask layer as claimed in claim 1, wherein a material of the first dielectric hard mask layer comprises plasma enhanced oxide (PEOX).

10. A rework method of a metal hard mask layer, comprising:
providing a material layer on which a dielectric layer, a metal hard mask layer, and a patterned dielectric hard mask layer are sequentially formed, wherein there is a defect on a region of the metal hard mask layer, and the region of the metal hard mask layer is not able to be patterned;
removing the defect; and
removing the region of the metal hard mask layer with use of an etchant until the dielectric layer is exposed, wherein the etchant has a high etching selectivity ratio with respect to the metal hard mask layer and the dielectric hard mask layer.

11. The rework method of the metal hard mask layer as claimed in claim 10, wherein a material of the metal hard mask layer comprises titanium nitride.

12. The rework method of the metal hard mask layer as claimed in claim 10, wherein a material of the dielectric hard mask layer comprises plasma enhanced oxide (PEOX).

13. The rework method of the metal hard mask layer as claimed in claim 10, wherein a material of the dielectric layer comprises tetra-ethyl-ortho-silicate (TEOS).

14. The rework method of the metal hard mask layer as claimed in claim 10, wherein the etchant comprises Cl₂/HBr.

15. A rework method of a metal hard mask layer, comprising:
providing a material layer on which a first dielectric layer, a second dielectric layer, a third dielectric layer, and a patterned first metal hard mask layer are sequentially formed, wherein the second dielectric layer, the third dielectric layer, and the patterned first metal hard mask layer have an opening, and the opening does not expose the first dielectric layer;
forming a fourth dielectric layer on the material layer, the fourth dielectric layer filling the opening;
removing the patterned first metal hard mask layer, the fourth dielectric layer, the third dielectric layer, and the second dielectric layer; and
sequentially forming a fifth dielectric layer, a sixth dielectric layer, a second metal hard mask layer, and a dielectric hard mask layer on the first dielectric layer.

16. The rework method of the metal hard mask layer as claimed in claim 15, wherein a method of forming the fourth dielectric layer comprises:
forming a dielectric material layer on the material layer, the dielectric material layer filling the opening and covering the patterned first metal hard mask layer; and
removing a portion of the dielectric material layer, a top surface of the patterned first metal hard mask layer being an end point of the removal step.

17. The rework method of the metal hard mask layer as claimed in claim 15, wherein a method of removing the patterned first metal hard mask layer comprises utilizing a metal etching machine.

18. The rework method of the metal hard mask layer as claimed in claim 15, wherein a method of removing the third dielectric layer comprises:
removing a portion of the third dielectric layer by performing a planarization process; and
removing the remaining third dielectric layer.

19. The rework method of the metal hard mask layer as claimed in claim 18, wherein a method of removing the remaining third dielectric layer comprises utilizing an etchant, the etchant having a high etching selectivity ratio with respect to the third dielectric layer and the second dielectric layer.

20. The rework method of the metal hard mask layer as claimed in claim 15, wherein a method of removing the second dielectric layer comprises utilizing an etchant, the etchant having a high etching selectivity ratio with respect to the second dielectric layer and the first dielectric layer.
